(19) United States
(12) Patent Application Publication
(10) Pub. No.: US 2012/0202348 A1
(43) Pub. Date: Aug. 9, 2012

(54) METHOD FOR FABRICATING SEMICONDUCTOR DEVICE

(75) Inventors: Mio TOMIYAMA, Tokyo (JP); Jun TAKAYASU, Mie (JP); Katsuyasu SHIBA, Mie (JP); Atsushi SHIGETA, Mie (JP)

(73) Assignee: Kabushiki Kaisha Toshiba, Tokyo (JP)

(21) Appl. No.: 13/238,693

(22) Filed: Sep. 21, 2011

(30) Foreign Application Priority Data
Feb. 7, 2011 (JP) 2011-024029

(51) Int. Cl. H01L 21/306

(52) U.S. Cl. 438/692; 257/E21.23

(57) ABSTRACT

A method for fabricating a semiconductor device according to an embodiment, includes forming a plurality of films above a substrate in a same chamber without transferring the substrate out of the chamber, forming a target film to be polished above the plurality of films, and polishing the target film by a chemical mechanical polishing (CMP) technique using a film on a front side among the plurality of films as a polishing stopper.

### CROSS-REFERENCE TO RELATED APPLICATION

This application is based upon and claims the benefit of priority from Japanese Patent Application No. 2011-024029 filed on Feb. 7, 2011 in Japan, the entire contents of which are incorporated herein by reference.

### FIELD

The present embodiment relates to a method for fabricating a semiconductor device.

### BACKGROUND

With increasingly higher integration and functionality of semiconductor integrated circuits (LSI), films deposited on substrates (wafers) are planarized by using a chemical mechanical polishing (CMP) process. For example, semiconductor devices are isolated from each other by isolating the semiconductor device regions from each other with a groove and then embedding a dielectric film in the groove. According to such an embedded device isolation method, the device regions are isolated from each other with a groove and then a dielectric film is deposited on the entire surface to embed the dielectric film in the groove and an extra portion of the dielectric film protruding from the groove is removed by the CMP process for planarization. In addition, for example, the CMP method is used for the so-called damascene method by which an embedded wire is formed by depositing a copper (Cu) film on a grooved dielectric film and removing the Cu film protruding from the groove by the CMP method.

Alternatively, after wires being formed, a dielectric film is deposited between the wires and an extra dielectric film protruding from the wires is removed by the CMP method for planarization.

In the CMP process for planarizing irregular wafer surface, the wafer is ground and polished as it is pressed onto a rotating polishing pad to which polishing slurry is supplied. Usually, a stopper film is formed below a film to be polished in advance so that polishing is stopped when the film to be polished formed on the wafer with a high selection ratio is polished to the stopper film. In such a case, the wafer surface may be flawed by aggregated polishing slurry or accidentally mixed other foreign matters. If the flaw is large, the flaw may be propagated to the film below the stopper film of CMP, resulting in cracks. As a result, troubles including breaking of wire damage electric characteristics of the device. Moreover, if a wafer is cracked, a chemical solution used for chemical cleaning after the CMP treatment infiltrates through the crack and if, for example, a metal material film is present in a lower layer, the metal material film is dissolved.

### BRIEF DESCRIPTION OF THE DRAWINGS

FIG. 1 is a flow chart showing principal portions of a method for fabricating a semiconductor device according to a first embodiment;

FIGS. 2A to 2D are sectional views showing processes performed corresponding to the flow chart of the method for fabricating a semiconductor device according to the first embodiment;

FIGS. 3A to 3C are sectional views showing processes performed corresponding to the flow chart of the method for fabricating a semiconductor device according to the first embodiment;

FIG. 4 is a conceptual diagram showing the configuration of a film forming apparatus according to the first embodiment;

FIG. 5 is a conceptual diagram showing an example of a cross section of the semiconductor device when polishing in the first embodiment is finished;

FIGS. 6A to 6D are sectional views showing processes performed corresponding to the flow chart of the method for fabricating a semiconductor device according to the first embodiment;

FIG. 7 is a sectional view showing a process performed corresponding to the flow chart of the method for fabricating a semiconductor device according to the first embodiment;

FIGS. 8A and 8B are conceptual diagrams for comparing states when a polished stopper film on a front side in the first embodiment is cracked;

FIG. 9 is a flow chart showing principal portions of the method for fabricating a semiconductor device according to a second embodiment;

FIGS. 10A to 10D are sectional views showing processes performed corresponding to the flow chart of the method for fabricating a semiconductor device according to the second embodiment;

FIGS. 11A to 11C are sectional views showing processes performed corresponding to the flow chart of the method for fabricating a semiconductor device according to the second embodiment;

FIG. 12 is a conceptual diagram showing an example of the cross section of the semiconductor device when polishing in the second embodiment is finished;

### DETAILED DESCRIPTION

A method for fabricating a semiconductor device according to an embodiment, includes forming a plurality of films above a substrate, forming a target film to be polished above the plurality of films, and polishing the target film to be polished by a chemical mechanical polishing (CMP) technique using a film on a front side among the plurality of films as a polishing stopper.

In the embodiments below, the method for fabricating a semiconductor device capable of inhibiting flaws from propagating to a film below the stopper film when polished by the CMP method will be described.

### First Embodiment

In the first embodiment, a case when a plurality of stopper films are formed after an opening is formed will be described below using the drawings.

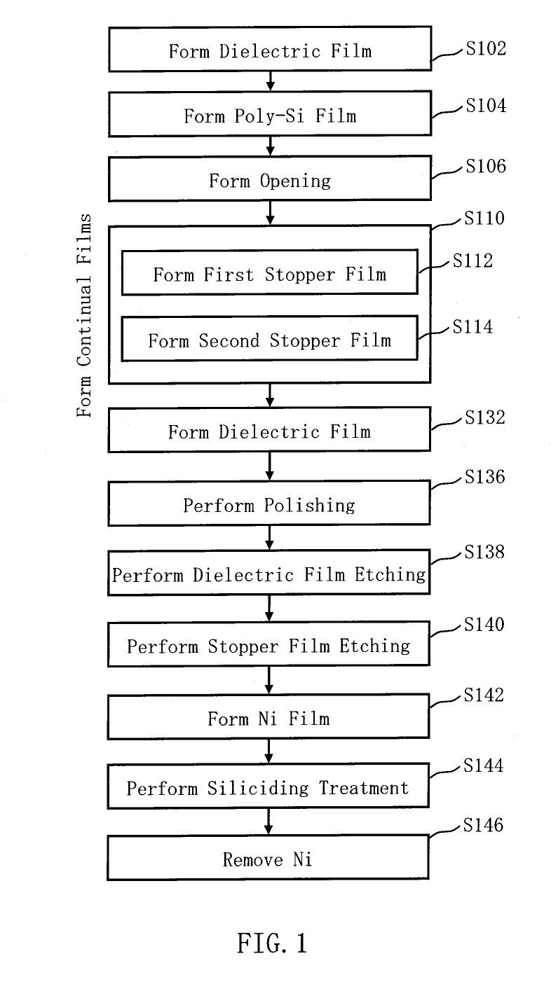

In FIG. 1, a series of processes including a dielectric film formation process (S102), a polysilicon (Si) film formation process (S104), an opening formation process (S106), a plurality of polishing stopper film formation processes (S110), a dielectric film formation process (S132), a polishing process (S136), a dielectric film etching process (S138), a polishing stopper film etching process (S140), a nickel (Ni) film formation process (S142), a siliciding treatment process (S144), and an Ni removal process (S146) are performed in the present embodiment. In the plurality of polishing stopper film formation processes (S110), a first stopper film formation process (S112) and a second stopper film formation process (S114) are performed as internal processes.

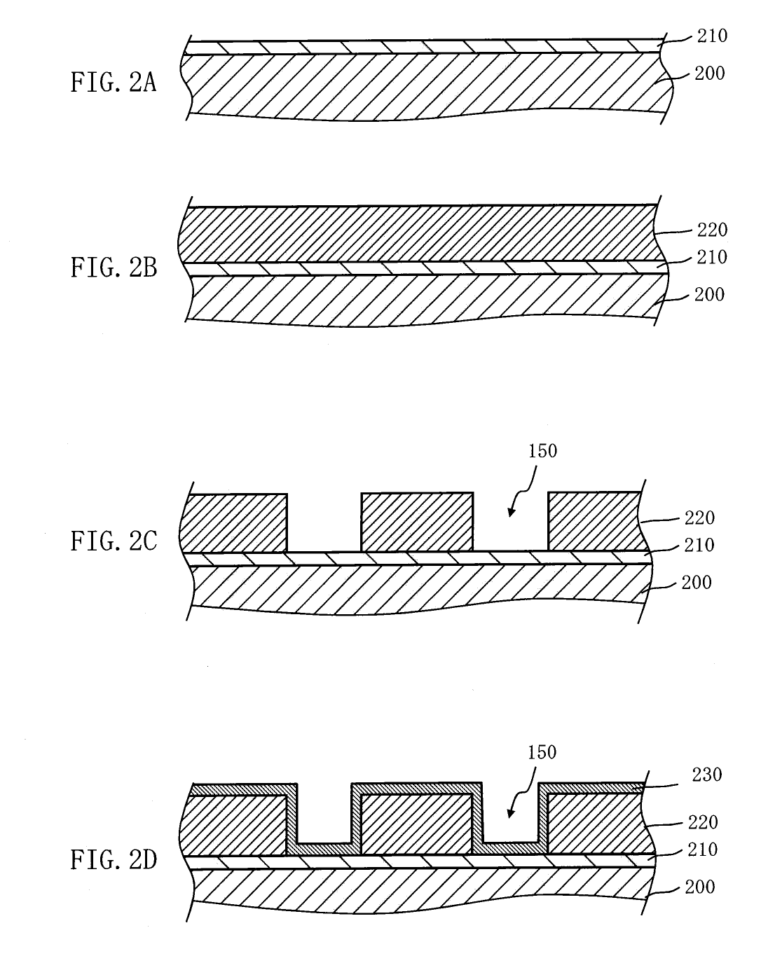

In FIGS. 2A to 2D, the dielectric film formation process (S102) to the first stopper film formation process (S112) in FIG. 1 are shown. The subsequent processes will be described later.

In FIG. 2A, as the dielectric film formation process (S102), a dielectric film 210 is formed on a semiconductor substrate 200 to a thickness of, for example, 2 to 20 nm. The dielectric film 210 functions as a gate dielectric film or tunnel dielectric film. As a formation method, preferably, the dielectric film 210 is formed by heat treatment (thermal oxidation treatment) in an oxygen atmosphere. For example, a silicon oxide (SiO₂) film is used as the dielectric film 210. As the semiconductor substrate 200, for example, a silicon wafer whose diameter is 300 mm is used.

In FIG. 2B, as the polysilicon (Si) film formation process (S104), a polysilicon film 220 is formed on the dielectric film 210 by using, for example, the chemical vapor deposition (CVD) method to a thickness of, for example, 50 nm. The polysilicon film 220 is illustrated here as a single-layer structure formed on the semiconductor substrate 200, but the polysilicon film 220 may have a laminated structure in which lower-layer and upper-layer silicon films are stacked via, for example, an inter-electrode dielectric film.

In FIG. 2C, as the opening formation process (S106), an opening 150, which is a groove structure to separate the polysilicon film 220 into a plurality of gates, is formed in the polysilicon film 220 by a lithography process and a dry etching process. The opening 150 can be formed substantially perpendicularly with respect to the surface of the semiconductor substrate 200 by removing the exposed polysilicon film 220 by the anisotropic etching method from the semiconductor substrate 200 having a resist film formed on the polysilicon film 220 through the lithography process such as a resist application process and exposure process. As an example, the opening 150 may be formed by the reactive ion etching (RIE) method. The resist film may be removed by ashing after the opening is formed. Before the dielectric film formation process (S132) shown in FIG. 1 after the polysilicon film 220 being processed into gates, an impurity diffusion layer may be formed by injecting impurity ions into the semiconductor substrate 200 between the plurality of gates.

Next, as the plurality of polishing stopper film formation processes (S110), a plurality of polishing stopper films (an example of a plurality of films) are formed successively on the semiconductor substrate 200 in the same chamber without being transferred out of the chamber. In the first embodiment, as an example, a case when two polishing stopper films 230, 232 are formed will be described. However, the polishing stopper film is not limited to be made into two layers. Polishing stopper films of three or more layers may be formed.

In FIG. 2D, as the first stopper film formation process (S112), a first polishing stopper film 230 is formed on the exposed polysilicon film 220 on the semiconductor substrate 200 and on an inner wall (side and bottom surfaces) of the opening 150 by using, for example, the CVD method to a thickness of, for example, 30 nm. For example, silicon nitride (SiN) is used as a material of the first polishing stopper film 230.

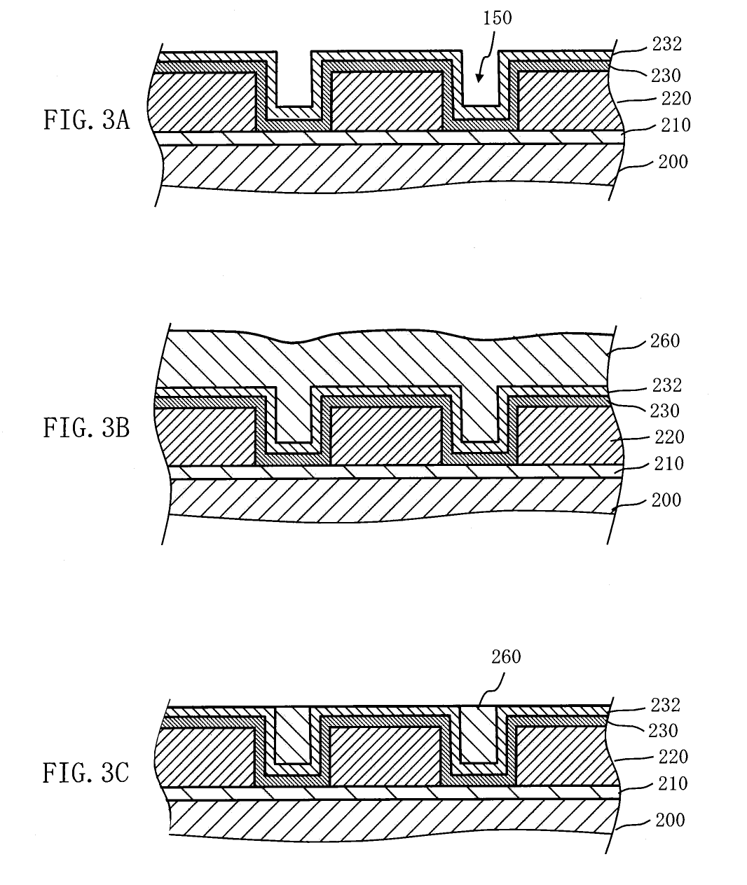

In FIGS. 3A to 3C, the second stopper film formation process (S114) to the polishing process (S136) in FIG. 1 are shown. The subsequent processes will be described later.

In FIG. 3A, as the second stopper film formation process (S114), the second polishing stopper film 232 is formed on top of the first polishing stopper film 230 by using, for example, the CVD method to a thickness of, for example, 30 nm. For example, silicon carbonitride (SiCN) is used as a material of the second polishing stopper film 232. Accordingly, two layers of the polishing stopper films 230, 232 are stacked on the exposed polysilicon film 220 of the semiconductor substrate 200 and on the inner wall (side and bottom surfaces) of the opening 150.

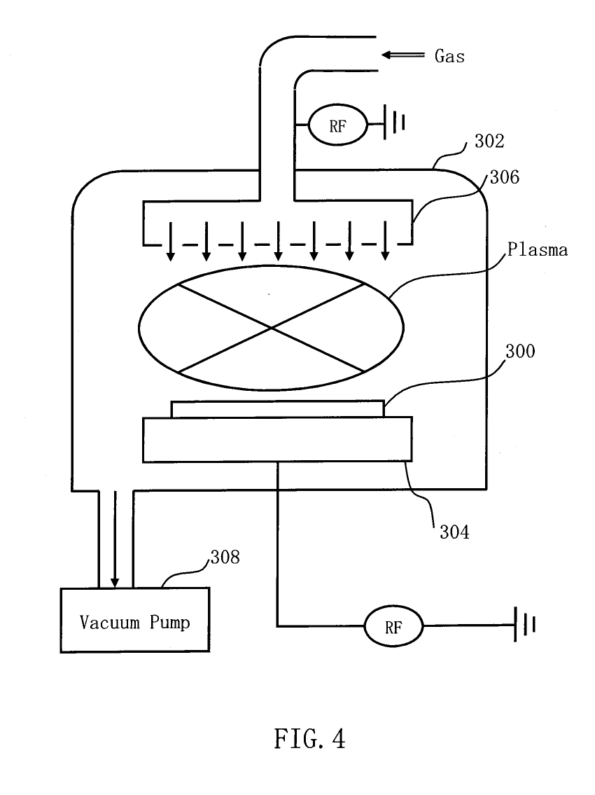

In FIG. 4, the configuration of a film forming apparatus according to the first embodiment is shown. In FIG. 4, a semiconductor substrate 300 in a state shown in FIG. 2C is placed on a lower electrode 304 which also serves as a substrate holder and whose temperature is controlled to a predetermined temperature inside a chamber 302. Then, gas for forming the first polishing stopper film 230 is supplied from inside an upper electrode 306 into the chamber 302. Plasma is generated by high-frequency power for forming the first polishing stopper film 230 by using a high-frequency power supply between the upper electrode 306 and the lower electrode 304 inside the chamber 302 evacuated to a desired gas pressure by a vacuum pump 308. The polishing stopper film 230 of the desired thickness is formed as described above. Then, after the formation of the polishing stopper film 230 is completed, for example, inert gas such as nitrogen (N₂), argon (Ar), or helium (He) is supplied (purged) to replace process gas remaining inside the chamber 302. Subsequently, gas for forming the second polishing stopper film 232 is supplied, while plasma is generated by high-frequency power for forming the second polishing stopper film 232. Subsequent to the first polishing stopper film 230, as described above, the second polishing stopper film 232 of the desired thickness is formed.

Incidentally, the first polishing stopper film 230 and the second polishing stopper film 232 are not limited to the above example of the film type and any material which can polish a material to be polished with a high selection ratio (any material in which a material to be polished can have a high polishing rate than the first polishing stopper film 230 and the second polishing stopper film 232) may be used. As the first and second polishing stopper films, for example, an SiN film, SiCN film, silicon oxynitride (SiON) film, silicon oxycarbide (SiOC) film, or BSG (Boro-Silicata Glass) film is preferably used. If film quality such as the film density and film stress is made different by changing film formation conditions, the same type of film may be used for the first and second polishing stopper films.

When an SiN film is formed, silane (SiH₄) gas and ammonium (NH₃) gas, for example, may be supplied as process gas. When an SiON film is formed, SiH₄ gas and N₂O gas, for example, may be supplied as process gas. When SiCN film is formed, (CH₃)₃SiH gas and NH₃ gas, for example, may be supplied as process gas. When SiOC film is formed, SiH₄ gas and CO₂ gas, for example, may be supplied as process gas. When BSG film is formed, SiH₄ gas and B₂H₆ gas, for example, may be supplied as process gas. By connecting various gas lines to one chamber 302, various types of film can be successively formed. Fabrication costs can be reduced by successively forming the plurality of polishing stopper films 230, 232 in the same chamber 302.

In FIG. 3B, as the dielectric film formation process (S132), a dielectric film 260 (target film to be polished) to be polished as described later is formed on the polishing stopper film 232 inside and outside the opening 150 to bury the whole opening 150 in which the polishing stopper films 230, 232 are formed. The dielectric film 260 is formed, for example, twice as thick as the depth of the opening 150 so that the whole opening 150 is reliably buried. For example, the CVD method may be applied as the formation method of the dielectric film 260. As the dielectric film 260, an SiO₂ film, for example, is used.

In FIG. 3C, as the polishing process (S136), with the CMP method (CMP technique), the dielectric film 260 is removed by polishing with the polishing stopper film 232 on the front side of the plurality of polishing stopper films as the polishing stopper. With the above process, the extra dielectric film 260 protruding from inside the opening 150 can be removed. When the polishing process (S136) is finished, the dielectric film 260 is embedded in the opening and the dielectric film 260 is exposed. On the other hand, the polishing stopper film 232 is exposed in locations other than the opening.

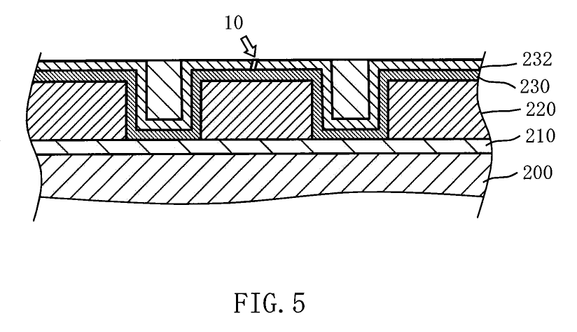

In FIG. 5, an example of the cross section of the semiconductor device when polishing in the first embodiment is finished, is shown. In the locations where the polishing stopper film 232 is exposed, an interface arises between the polishing stopper film 232 and the lower layer thereof, the polishing stopper film 230. Where there is an interface, atoms and molecules are bound discontinuously and thus, cracks are less likely to propagate. Moreover, with the presence of an interface, a force that is generated when a stress is added is more likely to be dispersed. Thus, even if a flaw 10 is made on the surface of the exposed polishing stopper film 232 by polishing slurry or accidentally mixed foreign matter in the polishing process (S136) as shown in FIG. 5, propagation of cracks is inhibited by the interface between the polishing stopper film 232 and the lower layer thereof, the polishing stopper film 230 so that generation of a crack that penetrates the lower layer thereof, the polishing stopper film 230, can be prevented. Therefore, the polysilicon film 220, the lower layer of the polishing stopper film 230, can be prevented from being flawed. Further, if chemical cleaning after polishing is performed, a chemical solution can be prevented from infiltrating up to the lower layer, the polysilicon film 220. Therefore, the semiconductor device can be prevented from being defective.

Two layers of the polishing stopper films 230, 232 are formed in the first embodiment, but as described above, three or more layers of polishing stopper film may also be formed. In that case, it is only necessary to be able to prevent propagation of a crack at least one layer before the lowest layer. The number of interfaces is increased by creating three or more layers so that safety can be promoted.

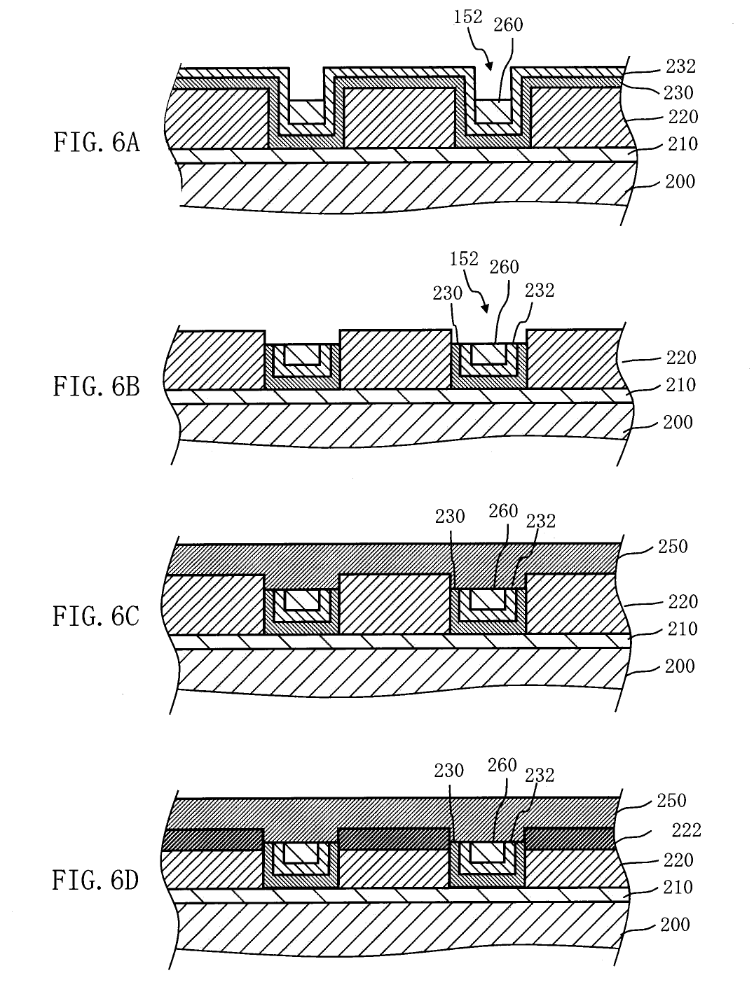

In FIGS. 6A to 6D, the dielectric film etching process (S138) to the siliciding treatment process (S144) in FIG. 1 are shown. The subsequent processes will be described later.

In FIG. 6A, as the dielectric film etching process (S138), the upper part of the exposed dielectric film 260 is removed by etching to form an opening 152. The upper part of the exposed dielectric film 260 is removed by, for example, dry etching. The depth (etching depth) of the opening 152 is preferably set so that the height position of the surface of the dielectric film 260 after the etching is lower than the height position of the surface of the polysilicon 220. Therefore, it is preferable to remove the upper part of the exposed the dielectric film 260 deeper than the total depth of the polishing stopper films 230, 232.

In FIG. 6B, as the polishing stopper film etching process (S140), the exposed polishing stopper film 232 and the lower layer thereof, the polishing stopper film 230 are removed together by wet etching. With the above process, the surface of the polysilicon film 220 is not only exposed but also made into a convex section configuration.

In FIG. 6C, as the nickel (Ni) film formation process (S142), an Ni film 250 is formed on the entire surface of the substrate. Thus, the Ni film 250 is formed on the surface of the exposed polysilicon film 220 and on the dielectric film 260.

In FIG. 6D, as the siliciding treatment process (S144), the surface of the polysilicon film 220 is silicified by heating (annealing) the substrate on which the Ni film 250 is formed. With that treatment, a nickel silicide (NiSi) film 222 can be formed in the upper part of the polysilicon film 220.

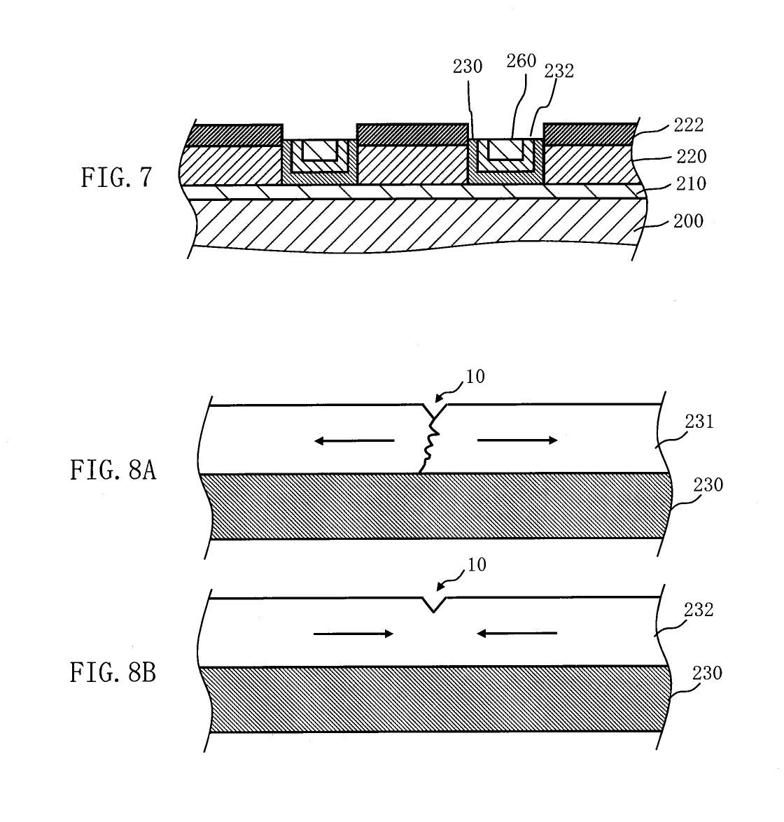

In FIG. 7, the Ni removal process (S146) in FIG. 1 is shown. In FIG. 7, as the Ni removal process (S146), the Ni film 250 that does not contribute to siliciding is removed by wet etching. As an etchant, for example, a mixed solution of sulfuric acid and hydrogen peroxide can be used. With the above process, as shown in FIG. 7, a semiconductor device in which the NiSi film 222 formed in the upper part of the polysilicon film 220 is exposed can be formed.

In the first embodiment, as described above, even if a crack is made in the polishing stopper film 232 of the upper layer, the advance of the crack can be stopped by an interface between the polishing stopper film 232 and the lower layer, the polishing stopper film 230. Therefore, cracks can be prevented from advancing in the polysilicon film 220, which is to be a conductive film, and in the NiSi film 222 in turn.

Among the plurality of polishing stopper films 230, 232, the polishing stopper film 232 on the front side is preferably a film on which a compressive stress acts.

Using FIGS. 8A and 8B, a film on which a tensile stress acts and a film on which a compressive stress acts when a crack is made in the polishing stopper film on the front side according to the first embodiment will be compared. FIG. 8A shows a case when a polishing stopper layer 231 on the front side of two layers is a layer on which a tensile stress acts. When a tensile stress acts on the polishing stopper layer 231 on the front side, if a flaw 10 is made on the surface of the polishing stopper layer 231, a stress is concentrated on the location where the flaw 10 is made because the polishing stopper layer 231 is pulled, so that the crack propagates toward the lower layer from the location where the flaw 10 is made. FIG. 8B shows, by contrast, a case when the polishing stopper layer 232 on the front side of the two layers is the film on which a compressive stress acts. When a compressive stress acts on the polishing stopper layer 232 on the front side, even if a flaw 10 is made on the surface of the polishing stopper layer 232, a crack is less likely to propagate from the location where the flaw 10 is made because a force acts in the direction in which the location where the flaw 10 is made is closed up. Therefore, the crack can be inhibited from propagating toward the lower layer and subsequent defects such as infiltration of a chemical solution or the like can be prevented. The film on which a compressive stress acts (compressive film) is a film for which the value of a film stress is positive.

### Second Embodiment

In the second embodiment, a case when a plurality of stopper films are formed before an opening is formed will be described below using the drawings.

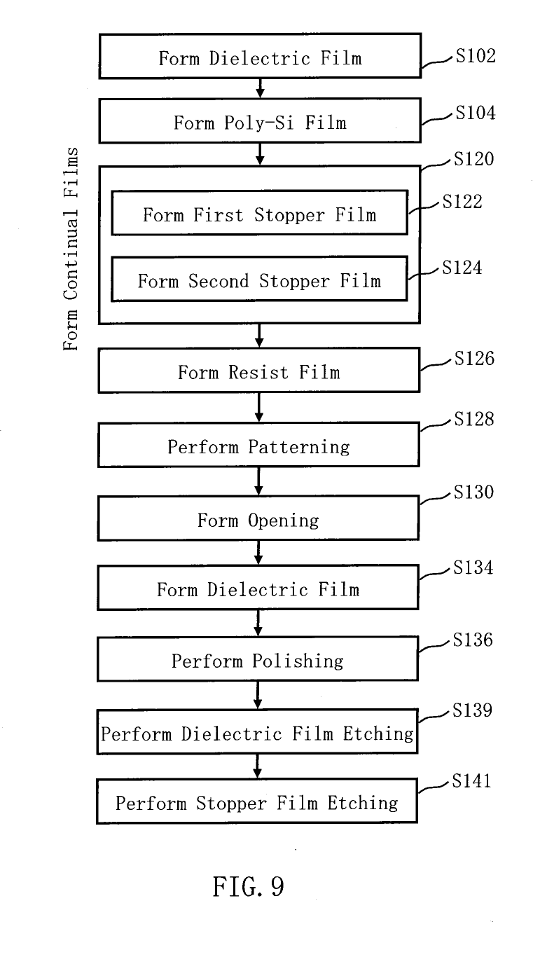

In FIG. 9, a series of processes including the dielectric film formation process (S102), the polysilicon (Si) film formation process (S104), a plurality of polishing stopper film formation processes (S120), a resist film formation process (S126), a patterning process (S128), an opening formation process (S130), a dielectric film formation process (S134), the polishing process (S136), a dielectric film etching process (S139), and a polishing stopper film etching process (S141) are performed in the present embodiment. In the plurality of polishing stopper film formation processes (S120), a first stopper film formation process (S122) and a second stopper film formation process (S124) are performed as internal processes.

What is not particularly mentioned below is the same as that in the first embodiment. The dielectric film formation process (S102) and the polysilicon film formation process (S104) are the same as those in the first embodiment. Thus, the subsequent processes from the state of FIG. 2B will be described.

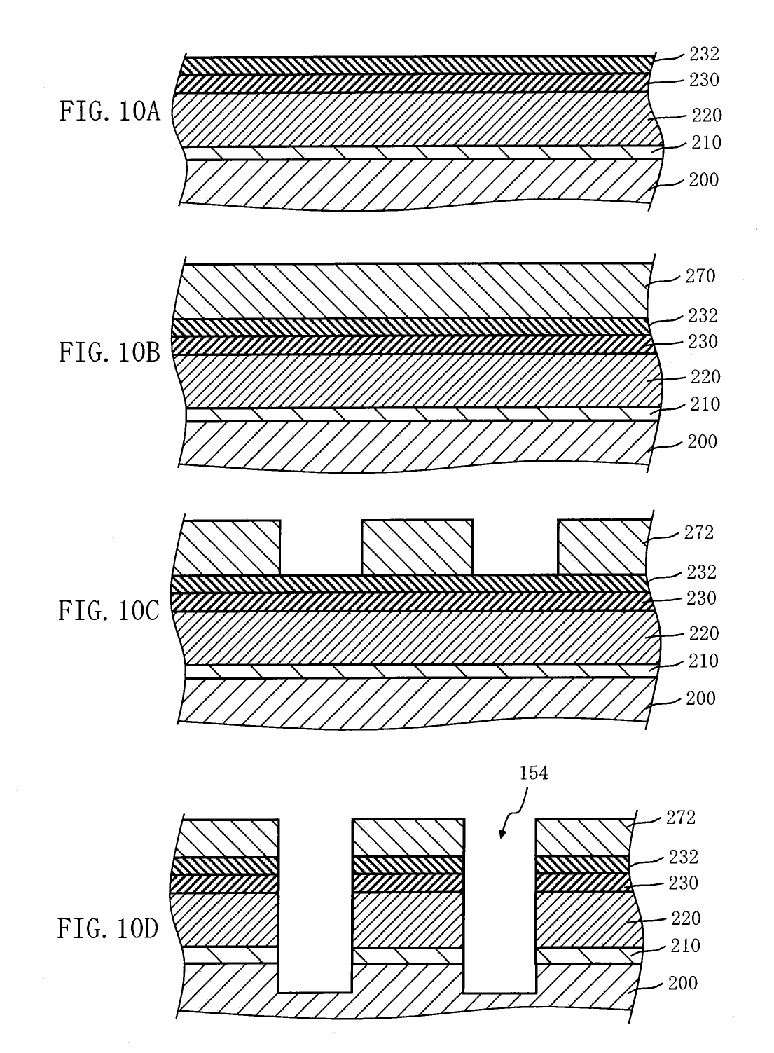

In FIGS. 10A to 10D, the plurality of polishing stopper film formation processes (S120) to the opening formation process (S130) in FIG. 9 are shown. The subsequent processes will be described later.

In FIG. 10A, as the plurality of polishing stopper film formation processes (S120), a plurality of polishing stopper films (an example of a plurality of films) are formed successively on the entire surface of a substrate in the same chamber without transferring the substrate out of the chamber. In the second embodiment, like in the first embodiment, a case when the two polishing stopper films 230, 232 are formed will be described as an example. However, the polishing stopper film is not limited to be made into two layers. Polishing stopper films of three or more layers may be formed. The polishing stopper films 230, 232 may be formed directly on the semiconductor substrate 200 by omitting the dielectric film formation process (S102) and the polysilicon film formation process (S104) shown in FIG. 9.

First, as the first stopper film formation process (S122), the first polishing stopper film 230 is formed on the exposed polysilicon film 220 on the semiconductor substrate 200 by using, for example, the CVD method to a thickness of, for example, 30 nm.

Then, as the second stopper film formation process (S124), the second polishing stopper film 232 is formed on top of the first polishing stopper film 230 by using, for example, the CVD method to a thickness of, for example, 30 nm. Accordingly, two layers of the polishing stopper films 230, 232 are stacked where the polysilicon film 220, ideally planarized, is formed on the entire surface of the semiconductor substrate 200. The formation method of the polishing stopper films 230, 232 is the same as that in the first embodiment.

As the first and second polishing stopper films, for example, an SiN film, SiCN film, silicon oxynitride (SiON) film, silicon oxycarbide (SiOC) film, or BSG (Boro-Silicata Glass) film is preferably used, as in the first embodiment. If film quality such as the film density and film stress is made different by changing film formation conditions, the same type of film may be used for the first and second polishing stopper films, also as in the first embodiment.

In FIG. 10B, as the resist formation process (S126), a resist film 270 is formed on the polishing stopper film 232 formed on the entire surface of the substrate.

In FIG. 100, as the patterning process (S128), a resist pattern 272 is formed by exposing a predetermined pattern and performing development processing using lithography technology.

In FIG. 10D, as the opening formation process (S130), an opening 154 as a groove structure to produce an element isolation region by a dry etching process is formed in the polishing stopper films 230, 232, the polysilicon film 220, the dielectric film 210, and the semiconductor substrate 200 using the resist pattern 272 as a mask. The depth in the semiconductor substrate 200 may be any depth with which elements can be isolated. The opening 154 can be formed substantially perpendicularly with respect to the surface of the semiconductor substrate 200 by removing the exposed polishing stopper films 230, 232 and lower layers thereof, the polysilicon film 220, the dielectric film 210, and the semiconductor substrate 200 halfway through the semiconductor substrate 200 by penetrating the exposed polishing stopper films 230, 232 and the lower layers thereof, the polysilicon film 220 and the dielectric film 210 by the anisotropic etching method and removing halfway through the semiconductor substrate 200 that has a resist film in the resist pattern 272 formed on the polysilicon film 220. As an example, the opening 154 may be formed by the reactive ion etching (RIE) method. The resist film may be left without ashing after the opening is formed.

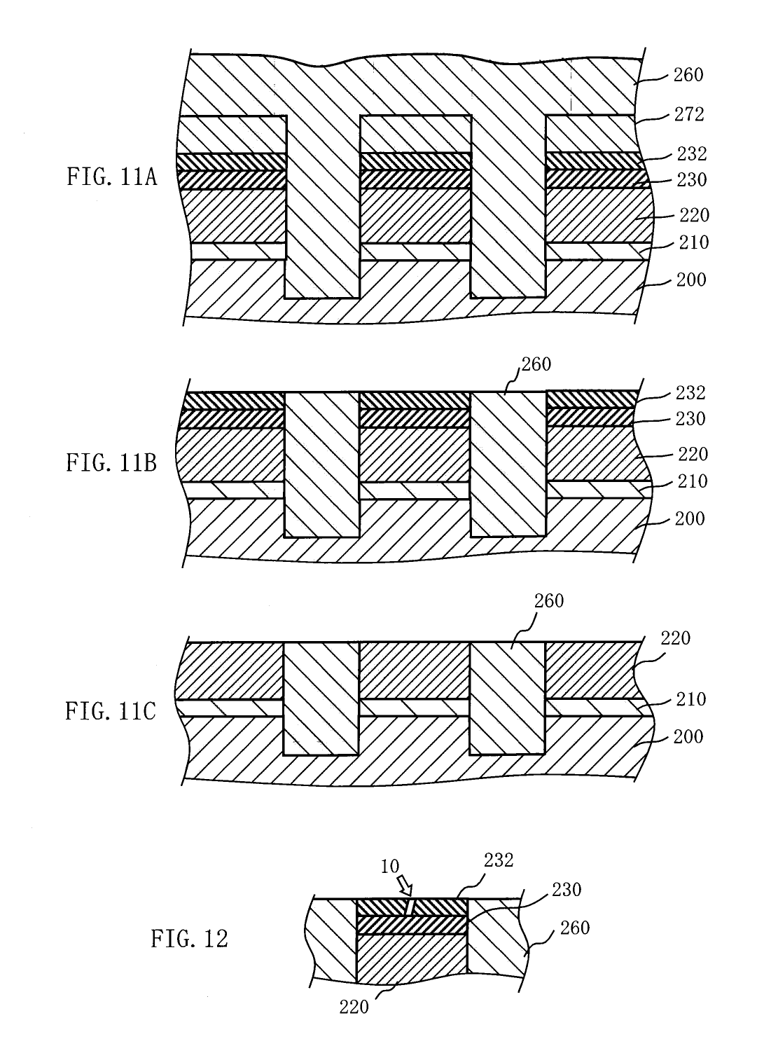

In FIGS. 11A to 11C, the dielectric film formation process (S134) to the polishing stopper film etching process (S141) in FIG. 9 are shown.

In FIG. 11A, as the dielectric film formation process (S134), the dielectric film 260 (target film to be polished) to be polished is formed inside the opening 154 and on the resist pattern 272 outside the opening 154 to bury the whole opening 154 which has none of the polishing stopper films 230, 232 formed on the inner wall (side and bottom surfaces). The dielectric film 260 is formed, for example, twice as thick as the depth of the opening 154 so that the whole opening 154 is reliably buried. As the dielectric film 260, for example, an SiO₂ film is used, which is the same as in the first embodiment.

In FIG. 11B, as the polishing process (S136), the dielectric film 260 and the lower layer thereof, the resist pattern 272, are removed together by polishing using the polishing stopper film 232 on the front side of the plurality of polishing stopper films as a polishing stopper by the CMP method. With the above process, the extra portion of the dielectric film 260 and the resist pattern 272 protruding from the opening 154 can be removed. By removing the extra dielectric film 260 and the resist pattern 272 together, a process to remove the resist pattern 272 by asking or the like can be omitted. When the polishing process (S136) is finished, the dielectric film 260 is embedded in the location where there was the opening and the dielectric film 260 is exposed. On the other hand, the polishing stopper film 232 is exposed in locations other than the opening.

In FIG. 12, an example of the cross section of the semiconductor device when polishing in the second embodiment is finished, is shown. In locations where the polishing stopper film 232 is exposed, an interface arises between the polishing stopper film 232 and the lower layer thereof, the polishing stopper film 230. Thus, as described above, a crack is less likely to propagate in locations where an interface is present. Also, a force when a stress is added is more likely to be dispersed. Thus, like in FIG. 5, even if the flaw 10 is made on the surface of the exposed polishing stopper film 232 due to polishing slurry or an accidentally mixed foreign matter in the polishing process (S136) as shown in FIG. 12, propagation of cracks is inhibited by the interface between the polishing stopper film 232 and the lower layer thereof, the polishing stopper film 230 so that a crack that pierces the polishing stopper film 230, the lower layer of the polishing stopper film 232 can be prevented. Therefore, the lower layer of the polishing stopper film 230, the polysilicon film 220, can be prevented from being flawed. Further, even if chemical cleaning after polishing is performed, a chemical solution can be prevented from infiltrating up to the lower layer, the polysilicon film 220. Therefore, the semiconductor device can avoid becoming defective.

Then, the upper part of the dielectric film 260 is removed by etching in the dielectric film etching process (S139) and the exposed polishing stopper film 232 and the lower layer thereof, the polishing stopper film 230 are removed together by wet etching in the polishing stopper film etching process (S141). With the above process, as shown in FIG. 11C, the surface of the polysilicon film 220 is exposed and also the polysilicon 220 and the dielectric film 260 can be provided with a flat section configuration. Alternatively, the dielectric film 260 may be removed deeper than the total depth of the polishing stopper films 230, 232 in the dielectric film etching process (S139) so that the polysilicon film 220 after the polishing stopper film etching process (S141) becomes convex.

Also in the second embodiment, as described above, the advance of a crack can be stopped by an interface between the polishing stopper films 230, 232 like in the first embodiment and therefore, the polysilicon film 220 to be a conductive film can be prevented from being damaged.

Also in the second embodiment, among the plurality of polishing stopper films 230, 232, the polishing stopper film 232 on the front side is preferably a film on which a compressive stress acts, which is the same as in the first embodiment. Further, particularly in the second embodiment, by using a compressive film for the polishing stopper film 232 on the front side, the width of the polishing stopper film 232 on the front side increasingly tends to be equal to or less than the width of the lower layer, the polishing stopper film 230, after the opening 154 for the element isolation is formed. Thus, burying properties in forming the dielectric film 260 to bury the opening 154 can be made better.

The embodiments have been described above with reference to the concrete examples. However, the present invention is not limited to the concrete examples. In the above embodiments, for example, a case when a plurality of polishing stopper films are applied in embedding a dielectric film after gates or semiconductor element regions being isolated by a groove. However, the application range of the method of polishing a film to be polished on a plurality of polishing stopper films by using the polishing stopper film on the upper-layer side as a stopper after the plurality of polishing stopper films are formed is not limited to the above examples. In addition, for example, the method may preferably be applied to the so-called damascene method by which an embedded wire is formed by depositing a copper (Cu) film on a grooved dielectric film and removing the protruding Cu film from the groove by the CMP method. Alternatively, the method may also be preferably applied to a case when, after wires being formed, a dielectric film is deposited between wires and an extra dielectric film protruding from between the wires is removed by the CMP method for planarization.

The thickness of inter-layer dielectric and the size, shape, and number of openings that are needed for semiconductor integrated circuits and various semiconductor elements can appropriately be selected and used.

In addition, all methods of fabricating an electronic component including all methods of fabricating a semiconductor device which include the elements of the present invention and can be attained by appropriately changing in design by a person skilled in the art are included in the scope of the invention.

Methods normally used in the semiconductor industry, for example, photolithography processes and cleaning before/after treatment are omitted for convenience of description, but needless to say, such methods are included in the scope of the invention.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A method for fabricating a semiconductor device, comprising:
forming a plurality of films above a substrate;
forming a target film to be polished above the plurality of films;
polishing the target film by a chemical mechanical polishing (CMP) technique using a film on a front side among the plurality of films as a polishing stopper; and
removing the plurality of films together after the target film has been polished, wherein the film on the front side among the plurality of films is a film on which a compressive stress acts.

2. The method according to claim 1, further comprising: forming an opening in the substrate before the plurality of films are formed,
wherein the plurality of films are formed on a surface of the substrate including an inner wall of the opening, the target film to be polished is formed on the plurality of films to bury the whole opening, and when the polishing is performed, the target film is polished and removed by using the film on the front side among the plurality of films formed outside the opening as the polishing stopper.

3. The method according to claim 1, further comprising:
forming a resist pattern after the plurality of films are formed and before the target film to be polished is formed; and
forming an opening penetrating the plurality of films using the resist pattern as a mask after the plurality of films are formed and before the target film to be polished is formed,
wherein the target film to be polished is formed above the plurality of films to bury the whole opening while the resist pattern used to form the opening being left behind, and when the polishing is performed, the target film and the resist pattern are polished and removed by using the film on the front side among the plurality of films formed outside the opening as the polishing stopper.

4. The method according to claim 1, further comprising:
forming a silicon film before the plurality of films are formed,
wherein the plurality of films are formed on the silicon film.

5. The method according to claim 4, further comprising: forming a nickel (Ni) film on the silicon film exposed after the plurality of films are removed.

6. The method according to claim 5, further comprising: performing siliciding treatment in a state in which the Ni film is formed on the silicon film.

7. The method according to claim 1, wherein the plurality of films are continuously formed by using a chemical vapor deposition (CVD) method.

8. The method according to claim 7, wherein the plurality of films have first and second films, and after a film formation process of the first film is finished, a process gas remaining in a process chamber is replaced by an inert gas and then, a film formation process of the second film is started.

9. The method according to claim 1, wherein a material, which makes a polishing rate of the target film to be polished higher than polishing rates of the plurality of films, is used for the plurality of films.

10. The method according to claim 9, wherein an oxide film are used as the target film to be polished.

11. The method according to claim 1, wherein the plurality of films are formed in such a way that atoms are bound discontinuously in an interface between adjacent films of the plurality of films.

12. The method according to claim 1, further comprising: removing a portion of the target film to be polished by etching after the target film has been polished and before the plurality of films are removed.

13. A method for fabricating a semiconductor device, comprising:
forming a plurality of films above a substrate in a same chamber without transferring the substrate out of the chamber;
forming a target film to be polished above the plurality of films; and
polishing the target film by a chemical mechanical polishing (CMP) technique using a film on a front side among the plurality of films as a polishing stopper.

14. The method according to claim 13, wherein the film on the front side among the plurality of films is a film on which a compressive stress acts.

15. The method according to claim 13, further comprising: removing the plurality of films together after the target film has been polished.

16. The method according to claim 13, further comprising: removing a portion of the target film to be polished by etching after the target film has been polished.

17. The method according to claim 13, further comprising:
forming an opening in the substrate before the plurality of films are formed,
wherein the plurality of films are formed on a surface of the substrate including an inner wall of the opening, the target film to be polished is formed on the plurality of films to bury the whole opening, and when the polishing is performed, the target film is polished and removed by using the film on the front side among the plurality of films formed outside the opening as the polishing stopper.

18. The method according to claim 13, further comprising:
forming a resist pattern after the plurality of films are formed and before the target film to be polished is formed; and
forming an opening penetrating the plurality of films using the resist pattern as a mask after the plurality of films are formed and before the target film to be polished is formed,
wherein the target film to be polished is formed above the plurality of films to bury the whole opening while the resist pattern used to form the opening being left behind, and when the polishing is performed, the target film and the resist pattern are polished and removed by using the film on the front side among the plurality of films formed outside the opening as the polishing stopper.

19. The method according to claim 13, wherein a material, which makes a polishing rate of the target film to be polished higher than polishing rates of the plurality of films, is used for the plurality of films.

20. The method according to claim 13, wherein when the plurality of films are formed, the plurality of films of an identical film type with different film qualities are formed by changing conditions of film formation.
